(19) United States
(12) Patent Application Publication
(10) Pub. No.: US 2025/0126819 A1
(43) Pub. Date: Apr. 17, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Ke-Jing YU, Kaohsiung (TW); Yen-Liang LIN, Tainan (TW); Ru-Shang HSIAO, Hsinchu (TW)

(21) Appl. No.: 18/486,649

(22) Filed: Oct. 13, 2023

(51) Int. Cl. H01L 29/66; H01L 29/78

(52) U.S. Cl. CPC H10D 30/024; H10D 1/042; H10D 1/716; H10D 30/6211; H10D 64/017

(57) ABSTRACT

A semiconductor device structure and methods of forming the same are described. In some embodiments, the structure includes a first region including a gate electrode disposed over a semiconductor fin, a second region, and a border region disposed between the first and second regions. The border region includes a metal-insulator-metal (MIM) structure, and the MIM structure includes a first conductive layer disposed over the semiconductor fin, a first dielectric layer in contact with the first conductive layer, and a second conductive layer in contact with the first dielectric layer. A top surface of the second conductive layer and a top surface of the gate electrode may be substantially co-planar.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-C, 2A-B, 3A-B, 4A-B, 5A-B, and 6A-B are various views of respective intermediate structures at intermediate stages in an example process of forming a semiconductor device structure, in accordance with some embodiments.

FIGS. 7A-B are various views of respective intermediate structures at the intermediate stage of FIGS. 6A and 6B in the example process of forming the semiconductor device structure, in accordance with some embodiments.

FIGS. 8 and 9 are cross-sectional views of intermediate structures at intermediate stages in the example process of forming the semiconductor device structure, in accordance with some embodiments.

FIGS. 10A-B are various views of a metal-insulator-metal (MIM) structure of FIG. 9, in accordance with some embodiments.

FIGS. 11A-B are various views of the MIM structure of FIG. 9, in accordance with alternative embodiments.

FIGS. 12A-B are various views of the MIM structure of FIG. 9, in accordance with alternative embodiments.

FIGS. 13A-C are cross-sectional side views of intermediate structures of the MIM structure of FIGS. 12A-B, in accordance with some embodiments.

FIGS. 14A-C are various views of a MIM structure, in accordance with some embodiments.

FIGS. 15A-D, 16A-B, 17A-B, 18A-B, and 19A-B are various views of respective intermediate structures at intermediate stages in an example process of forming the semiconductor device structure including the MIM structure of FIGS. 14A-C, in accordance with some embodiments.

FIGS. 20A-B are top views of the MIM structure of FIGS. 11A-B or the MIM structure of FIGS. 19A-B, in accordance with alternative embodiments.

FIGS. 21A-C are cross-sectional views of intermediate structures at intermediate stages in the example process of forming the semiconductor device structure, in accordance with some embodiments.

FIGS. 22A-C are cross-sectional views of intermediate structures at intermediate stages in the example process of forming the semiconductor device structure, in accordance with some embodiments.

FIGS. 23A-B are various views of a MIM structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

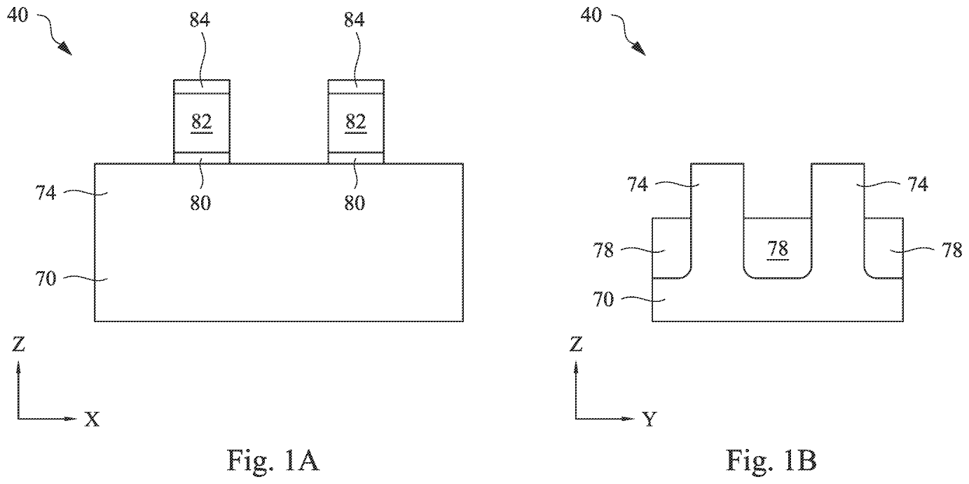

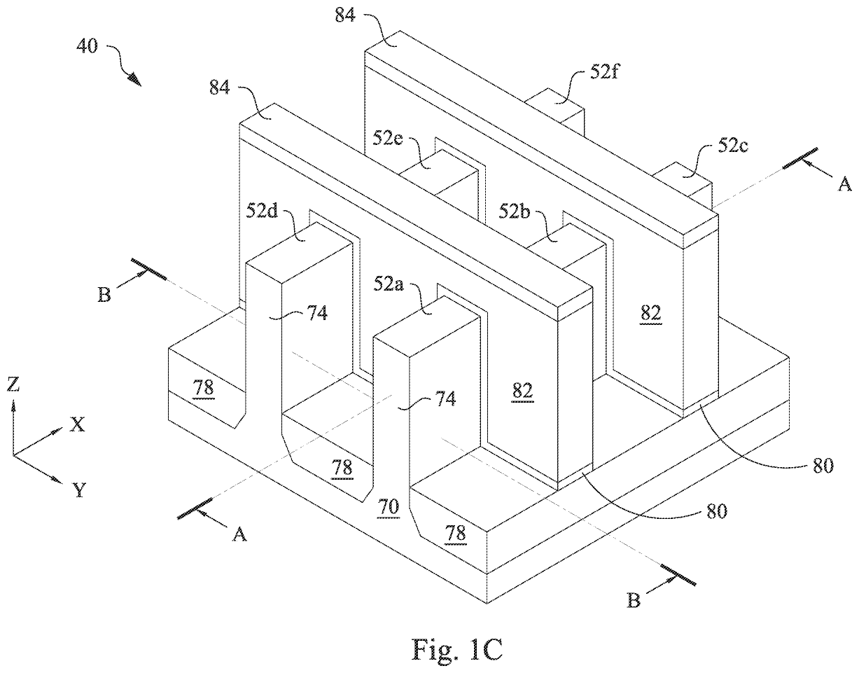

FIGS. 1-22B show processes for manufacturing a semiconductor device structure 40 according to embodiments of the present disclosure. It is understood that additional operations can be provided before, during, and after processes shown by FIGS. 1-22B, and some of the operations described below can be replaced or eliminated, for additional embodiments of the method. The order of the operations/processes is not limiting and may be interchangeable.

FIGS. 1A, 1B, and 1C illustrate different views of an intermediate structure at a stage in an example process of forming a semiconductor device structure 40, in accordance with some embodiments. FIGS. 1A and 1B are different cross-sectional views of the intermediate structure, and FIG. 1C is a perspective view of the intermediate structure.

As shown in FIGS. 1A-1C, fins 74 are formed from a semiconductor substrate 70. The fins 74 are semiconductor fins. Isolation regions 78 are disposed on the semiconductor substrate 70 and are disposed between neighboring fins 74. The fins 74 each protrude above and from between neighboring isolation regions 78. Sacrificial gate stacks (or more generically, sacrificial gate structures), with each including a dielectric layer 80, a sacrificial gate layer 82, and a mask 84, are formed along sidewalls and over top surfaces of the fins 74. Source/drain regions 52a-f are located in respective regions of the fins 74.

FIG. 1C further illustrates reference cross-sections that are used in other figures. Cross-section A-A is in a plane along the fin 74. Cross-section B-B is in a plane perpendicular to the cross-section A-A and is across source/drain regions 52a and 52d of neighboring fins 74. Figures refer to these reference cross-sections for clarity. Figures ending with an “A” designation in FIGS. 1A to 6B illustrate cross-sectional views at various instances of processing corresponding to cross-section A-A, and figures ending with a “B” designation in FIGS. 1A to 6B illustrate cross-sectional views at various instances of processing corresponding to cross-section B-B.

The semiconductor substrate 70 may be or include a bulk semiconductor substrate, a semiconductor-on-insulator (SOI) substrate, or the like, which may be doped (e.g., with a p-type or an n-type dopant) or undoped. In some embodiments, the semiconductor material of the semiconductor substrate may include an elemental semiconductor including silicon (Si) or germanium (Ge); a compound semiconductor; an alloy semiconductor; or a combination thereof.

The fins 74 may be formed from the semiconductor substrate 70, such as by etching trenches between the fins 74. The isolation regions 78 may be formed in trenches between the fins 74. The isolation regions 78 may include or be an insulating material such as an oxide (such as silicon oxide), a nitride, the like, or a combination thereof. The fins 74 protrude from between neighboring isolation regions 78, which may, at least in part, thereby delineate the fins 74 as active areas on the semiconductor substrate 70. The fins 74 and isolation regions 78 may be formed by any acceptable processes and can include any acceptable material. In some examples, the fins 74 may include heteroepitaxial structures (e.g., a material lattice-mismatched to the semiconductor material of the semiconductor substrate 70) or other structures.

The sacrificial gate stacks are formed over and extend laterally perpendicularly to the fins 74. Each sacrificial gate stack includes the dielectric layer 80, the sacrificial gate layer 82, and the mask 84. The dielectric layer 80 may include or be silicon oxide, silicon nitride, the like, or multilayers thereof. The sacrificial gate layer 82 may include or be silicon (e.g., polysilicon) or another material. The masks 84 may include or be silicon nitride, silicon oxynitride, silicon carbon nitride, the like, or a combination thereof. The layers for the masks 84, sacrificial gate layer 82, and dielectric layer 80 may be deposited and patterned into the sacrificial gate stacks using any acceptable processes to form the mask 84, sacrificial gate layer 82, and dielectric layer 80 for each sacrificial gate stack.

FIGS. 2A and 2B illustrate the formation of a first gate spacer layer 86 along sidewalls and top surfaces of the sacrificial gate stacks and the fins 74. The first gate spacer layer 86 is conformally deposited along sidewalls and top surfaces of the fins 74 and sacrificial gate stacks (e.g., along sidewalls of dielectric layers 80, sacrificial gate layers 82, and masks 84, and on top surfaces of masks 84), and on top surfaces of the isolation regions 78. The first gate spacer layer 86 can be or include silicon oxycarbonitride (SiOCN), silicon oxycarbide (SiOC), or another material. In some examples, the first gate spacer layer 86 can be deposited using an atomic layer deposition (ALD) process, although other deposition techniques can be used. In some embodiments, the first gate spacer layer 86 may be omitted.

FIGS. 3A and 3B illustrate the formation of a second gate spacer layer 88. The second gate spacer layer 88 is conformally deposited on the first gate spacer layer 86. The second gate spacer layer 88 is a dielectric layer including silicon, oxygen, nitrogen and carbon. In some embodiments, the second gate spacer layer 88 can be or include a silicon oxycarbonitride (SiOCN). The second gate spacer layer 88 may be deposited by an ALD process.

FIGS. 4A and 4B illustrate the formation of gate spacers including respective portions of the first gate spacer layer 86 and the second gate spacer layer 88. Gate spacers (e.g., bi-layer gate spacers, as illustrated) are formed along sidewalls of the gate stacks (e.g., sidewalls of the dielectric layer 80, sacrificial gate layer 82, and mask 84) and over the fins 74. Residual gate spacers may also remain along sidewalls of the fins 74, for example, depending on the height of the fins 74 above the isolation regions 78. The gate spacers may be formed by anisotropically etching the second gate spacer layer 88 and the first gate spacer layer 86. The etch process can include a RIE, NBE, or another etch process. The multi-layer gate spacers may include additional and/or different layers and/or materials in other embodiments.

FIGS. 5A and 5B illustrate the formation of source/drain regions 92. Recesses are formed in the fins 74 on opposing sides of the sacrificial gate stacks, and the source/drain regions 92 are formed in the recesses. The recessing can be by an etch process. The etch process can be isotropic or anisotropic, or further, may be selective with respect to one or more crystalline planes of the semiconductor substrate 70. As shown in FIGS. 5A and 5B, epitaxy source/drain regions 92 may be formed in the recesses. The epitaxy source/drain regions 92 may include or be silicon germanium, silicon carbide, silicon phosphorus, a III-V compound semiconductor, a II-VI compound semiconductor, or the like. The epitaxy source/drain regions 92 may be formed in the recesses by epitaxially growing a material in the recesses, such as by metal-organic CVD (MOCVD), molecular beam epitaxy (MBE), liquid phase epitaxy (LPE), vapor phase epitaxy (VPE), selective epitaxial growth (SEG), the like, or a combination thereof. The epitaxy source/drain regions 92 may extend beyond sidewalls and top surfaces of the fins 74 (e.g., are raised) and may have facets, which may correspond to crystalline planes of the semiconductor substrate 70. In some examples, different materials are used for epitaxy source/drain regions 92 for p-type devices and n-type devices. Appropriate masking during the recessing or epitaxial growth may permit different materials to be used in different devices. In this disclosure, a source region and a drain region are interchangeably used, and the structures thereof are substantially the same. Furthermore, source/drain region(s) may refer to a source or a drain, individually or collectively dependent upon the context.

As shown in FIGS. 6A and 6B, after the formation of the source/drain regions 92, a contact etch stop layer (CESL) 96 is conformally deposited by any acceptable process, on surfaces of the epitaxy source/drain regions 92, sidewalls and top surfaces of the multi-layer gate spacers, top surfaces of the mask 84, and top surfaces of the isolation regions 78. Generally, an etch stop layer can provide a mechanism to stop an etch process when forming, e.g., contacts or vias. An etch stop layer may be formed of a dielectric material having a different etch selectivity from adjacent layers or components. The CESL 96 may include silicon nitride, silicon carbon nitride, the like, or a combination thereof.

A first interlayer dielectric (ILD) 100 may be formed over the CESL 96. The first ILD 100 may include or be silicon dioxide, a low-k dielectric material, such as silicon oxynitride, phosphosilicate glass (PSG), borosilicate glass (BSG), borophosphosilicate glass (BPSG), undoped silicate glass (USG), fluorinated silicate glass (FSG), organosilicate glasses (OSG), SiOₓC_{y}, spin-on-glass, spin-on-polymers, silicon carbide material, a compound thereof, a composite thereof, the like, or a combination thereof. The first ILD 100 may be deposited by any acceptable process.

The first ILD 100 and CESL 96 are formed with top surfaces coplanar with top surfaces of the sacrificial gate layers 82. A planarization process, such as a chemical mechanical polishing (CMP), may be performed to level the top surface of the first ILD 100 and CESL 96 with the top surfaces of the sacrificial gate layers 82. The CMP may also remove the mask 84 (and, in some instances, upper portions of the multi-layer gate spacers) on the sacrificial gate layers 82. Accordingly, top surfaces of the sacrificial gate layers 82 are exposed through the first ILD 100 and the CESL 96, as shown in FIGS. 6A and 6B. In some embodiments, after the CMP process, the first ILD 100 may be recessed, and a dielectric material (not shown) may be formed on the first ILD 100. The dielectric material may be a nitride, such as silicon nitride. Another planarization process may be performed so the top surface of the dielectric material and the top surfaces of the sacrificial gate layers 82 may be substantially co-planar. The dielectric material may protect the first ILD 100 during subsequent processes.

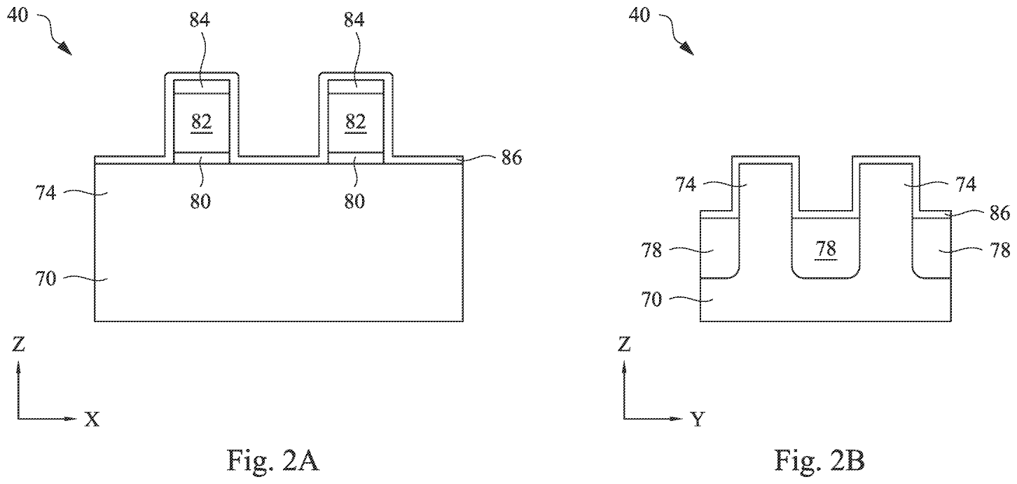

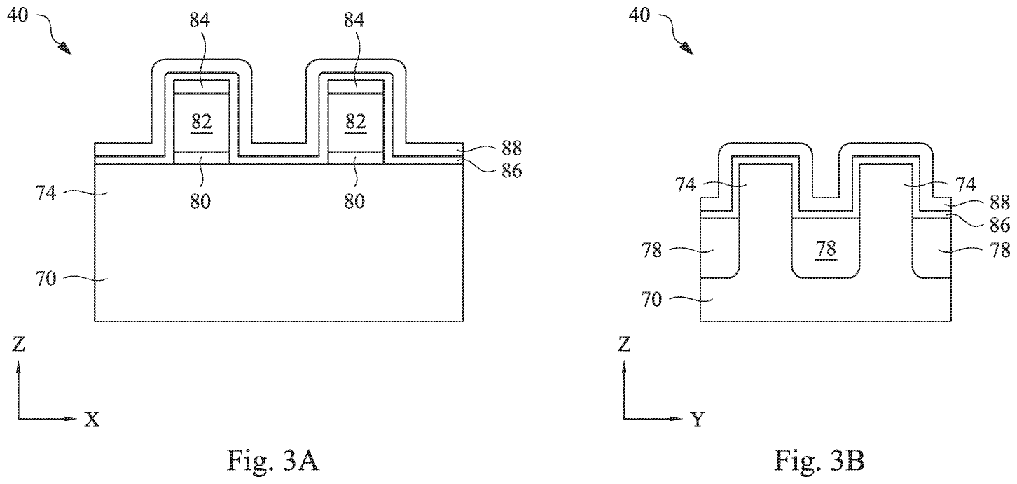

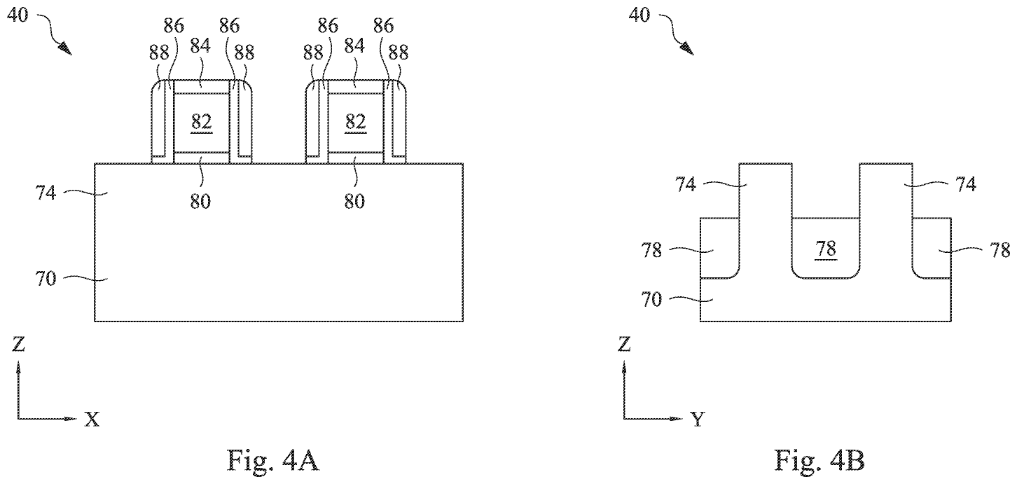

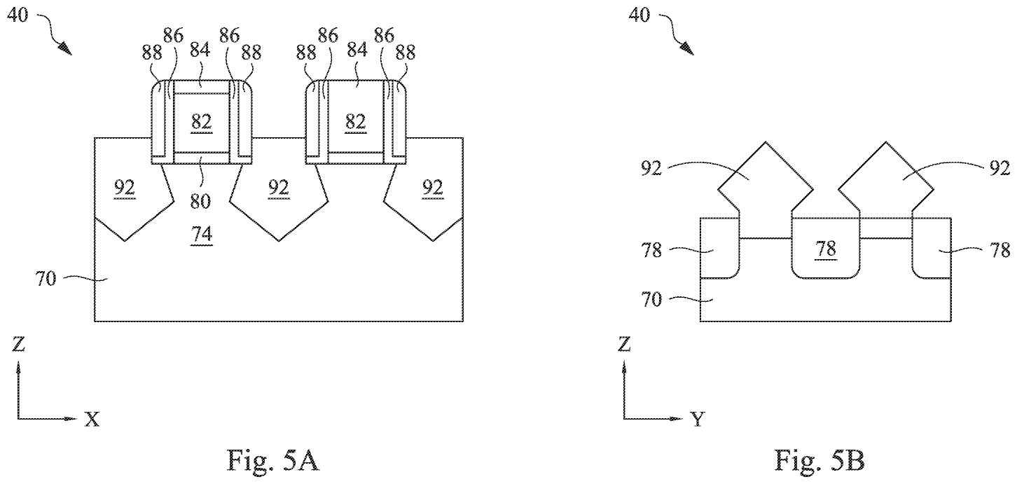

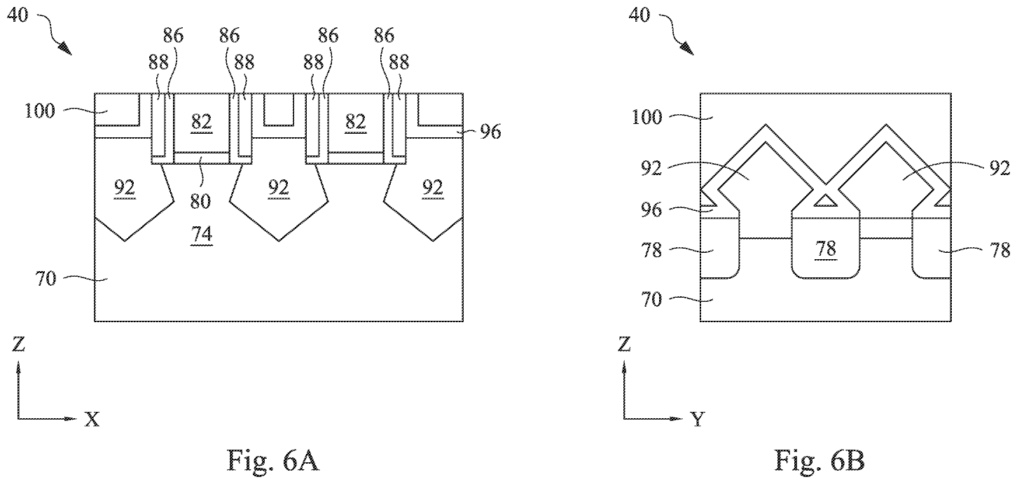

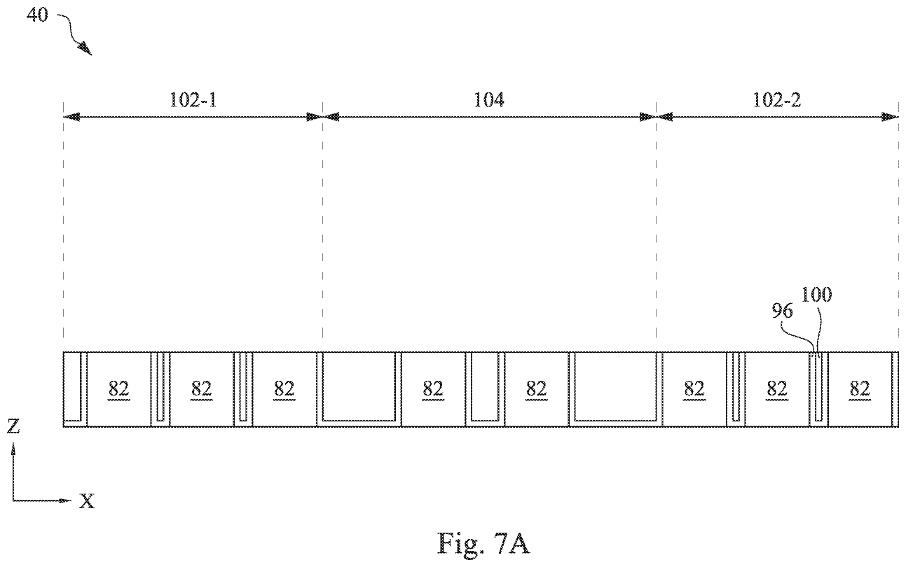

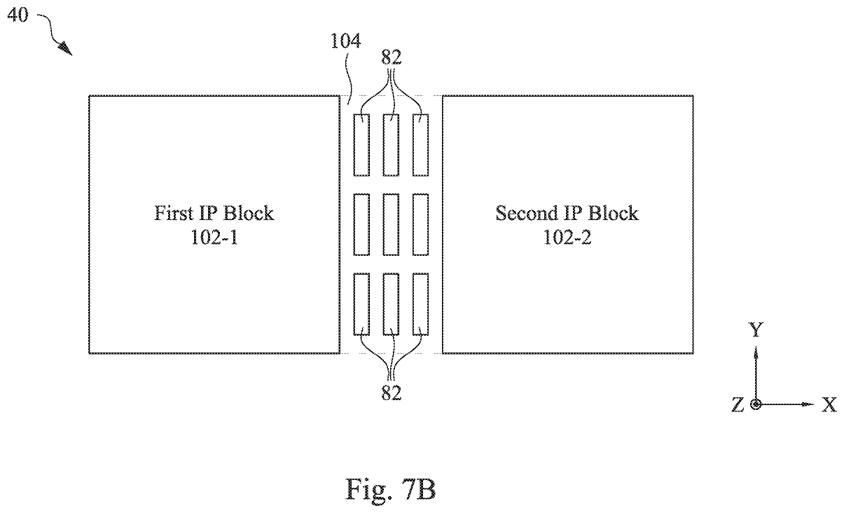

FIGS. 7A-B are cross-sectional views of respective intermediate structures at the intermediate stage of FIGS. 6A and 6B in the example process of forming the semiconductor device structure 40, in accordance with some embodiments. As shown in FIG. 7A, the semiconductor device structure 40 includes a first IP block 102-1 and a second IP block 102-2. An IP block is a reusable unit of logic, cell, or IC layout design that is the intellectual property of one party or one vendor. IC designers can use these IP blocks as building blocks. The first IP block 102-1 is a reusable unit of logic, cell, or IC layout design; the second IP block 102-2 is another reusable unit of logic, cell, or IC layout design. In one example, the first IP block 102-1 is a static random access memory (SRAM) IP block, the second IP block 102-2 is another SRAM IP block. The density of gate structures (or sacrificial gate structures) in these SRAM IP blocks is relatively high. It should be understood that the example shown in FIG. 7A is exemplary rather than limiting, and the semiconductor device structure 40 may include more than two IP blocks in other embodiments.

As shown in FIG. 7A, a border region 104 is located between the first IP block 102-1 and the second IP block 102-2 in a first horizontal direction (i.e., the X direction). In some embodiments, the fins 74 continuously extend from the first IP block 102-1 through the border region 104 and into the second IP block 102-2. In some embodiments, the continuous fins 74 may be patterned to form discrete fins 74 in the first IP block 102-1, the border region 104, and the second IP block 102-2. Regardless of the fins 74 being continuous or discrete, the fins 74 in the first and second IP blocks 102-1, 102-2 may be the same fins 74 in the border region 104, because the fins 74 in the first and second IP blocks 102-1, 102-2 and the border region 104 are formed at the same time. As shown in FIG. 7B, which is a top view of the semiconductor device structure 40 of FIG. 7A, the border region 104 has a width in the first horizontal direction (i.e., the X direction) and a length in the second horizontal direction (i.e., the Y direction). In one example, the width of the border region 104 is between 0.1 μm and 3.0 μm. The density of gate structures (or sacrificial gate structures) in the border region 104 is relatively low compared to the density of gate structures in the IP blocks. FIG. 7A illustrates the density of the sacrificial gate layers 82, which represents the sacrificial gate structures, in the IP blocks 102-1, 102-2 is greater than the density of the sacrificial gate layers 82 in the border region 104. The gate spacer layers 86, 88, the dielectric layers 80, the fins 74, and the semiconductor substrate 70 are omitted in FIG. 7A for clarity. In some embodiments, during the replacement gate (RPG) process, CMP dishing effect can cause under-polish defects in integrated circuits (ICs) having two or more IP blocks and border regions therebetween. For example, the metal gates that replace the sacrificial gate layers located in the IP blocks adjacent the border region may have a height substantially less than a height of the metal gates located in the center of the IP blocks.

It should be understood that the range from 0.1 μm to 3.0 μm is not chosen arbitrarily. For border regions wider or longer than 3.0 μm, large dummy patterns (including large or spacious sacrificial gate layer patterns and large or spacious dummy fin patterns) have been employed. It should be understood that the embodiments disclosed herein can replace the large dummy patterns in border regions wider or longer than 3.0 μm. For border regions narrower or shorter than 0.1 μm, CMP dishing effect is not severe enough to cause a problematic under-polish effect because the border region is not large enough.

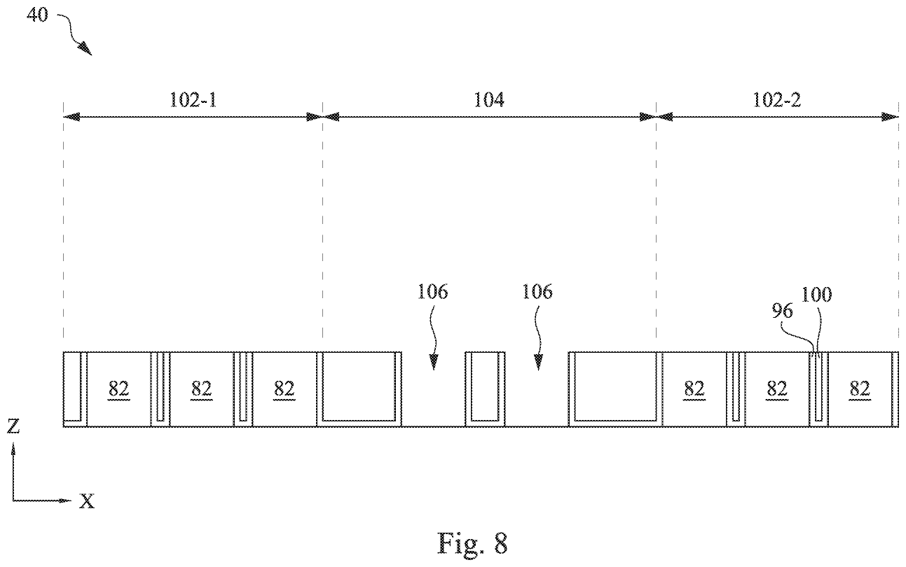

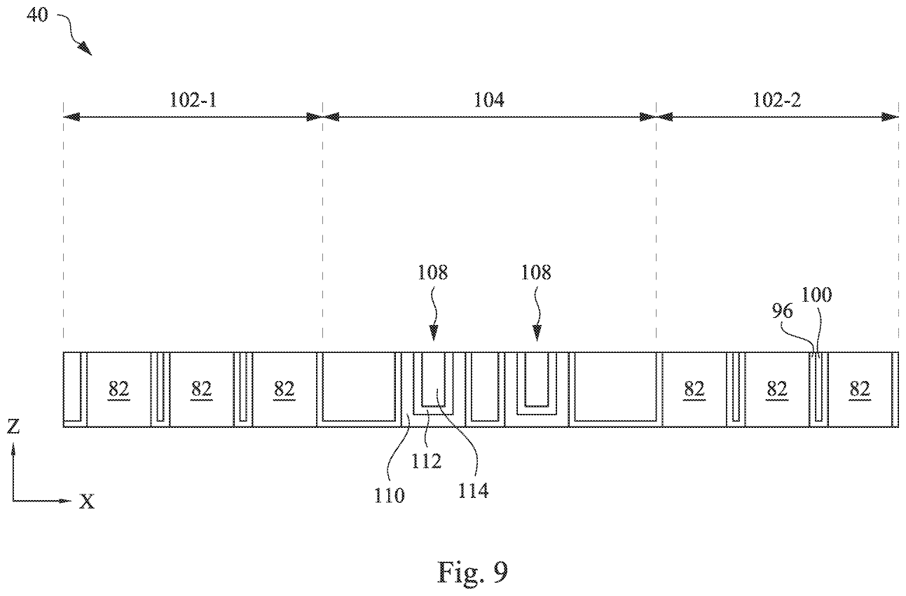

FIGS. 8 and 9 are cross-sectional views of intermediate structures at intermediate stages in the example process of forming the semiconductor device structure 40, in accordance with some embodiments. As shown in FIG. 8, a mask layer (not shown) is formed in the first and second IP blocks 102-1, 102-2 to protect the materials in the first and second IP blocks 102-1, 102-2, and the exposed sacrificial gate layers 82 in the border region 104 are removed. The sacrificial gate layers 82 may be removed by an etch process selective to the gate layers 82, wherein the dielectric layers 80 act as etch stop layers. In some embodiments, one or more etch processes may be performed subsequently to remove the dielectric layers 80 and the gate spacer layers 86, 88. The etch processes can be, for example, a RIE, NBE, a wet etch, or another etch process. In some embodiments, the dielectric layers 80 are not removed. As shown in FIG. 8, openings 106 are formed in the border regions 104 after the removal of the sacrificial gate layers 82, the gate spacer layers 86, 88, and in some embodiments, the dielectric layers 80. Portions of the fins 74 may be exposed after the removal of the sacrificial gate layers 82, the gate spacer layers 86, 88, and the dielectric layers 80.

As shown in FIG. 9, a metal-insulator-metal (MIM) structure 108 is formed in each opening 106. The MIM structure 108 may include one or more MIM capacitors. In some embodiments, as shown in FIG. 9, the MIM structure 108 includes a first conductive layer 110, a dielectric layer 112 disposed on the first conductive layer 110, and a second conductive layer 114 disposed on the dielectric layer 112. In some embodiments, the first and second conductive layers 110, 114 each includes a metal or a metal nitride. For example, the first and second conductive layers 110, 114 each includes titanium nitride (TiN), tantalum nitride (TaN), tungsten nitride (WN), ruthenium (Ru), iridium (Ir), platinum (Pt), or combinations thereof. In some embodiments, the first conductive layer 110 and the second conductive layer 114 includes the same material. In some embodiments, the dielectric layer 112 includes a high-k dielectric material, such as zirconium oxide (ZrO₂). Alternatively, the dielectric layer 112 may include one or more layers of silicon oxide (SiO₂), silicon nitride (Si₃N₄), silicon oxynitride (SiON), aluminum oxide (Al₂O₃), hafnium silicates (HfSiON), tantalum oxide (Ta₂O₅), hafnium oxide (HfO₂), titanium oxide (TiO₂), barium strontium titanate (BST), strontium titanate oxide (STO), or combinations thereof. The MIM structures 108 may be in contact with the exposed portions of the fins 74 (if the dielectric layers 80 are removed) or the dielectric layers 80.

In some embodiments, the MIM structure 108 may be formed by first forming the first conductive layer 110 in the opening 106. The first conductive layer 110 may be a conformal layer formed by a conformal process, such as an ALD process. The dielectric layer 112 is then formed on the first conductive layer 110 in the opening 106, and the dielectric layer 112 may be a conformal layer formed by a conformal process. Next, the second conductive layer 114 is formed on the dielectric layer 112 to fill the opening 106. Portions of the first conductive layer 110, the dielectric layer 112, and the second conductive layer 114 may be formed on the mask layer (not shown) formed in the IP blocks 102-1, 102-2, and a CMP process may be performed to remove the portions of the first conductive layer 110, the dielectric layer 112, and the second conductive layer 114 formed on the mask layer located in the IP blocks 102-1, 102-2. The mask layer located in the IP blocks 102-1, 102-2 may be also removed by the CMP process, and the resulting structure is shown in FIG. 9.

The MIM structures 108 in the border region 104 reduces the CMP dishing effect, because the MIM structure 108 includes different materials. In addition, the MIM structures 108 offer MIM capacitors in front-end-of-line (FEOL), which may conserve metal routing to reduce IR drop compared to MIM capacitors in back-end-of-line (BEOL). It should be understood that the example of the MIM structure 108 shown in FIG. 9 is exemplary rather than limiting, and the MIM structure 108 may have different configurations.

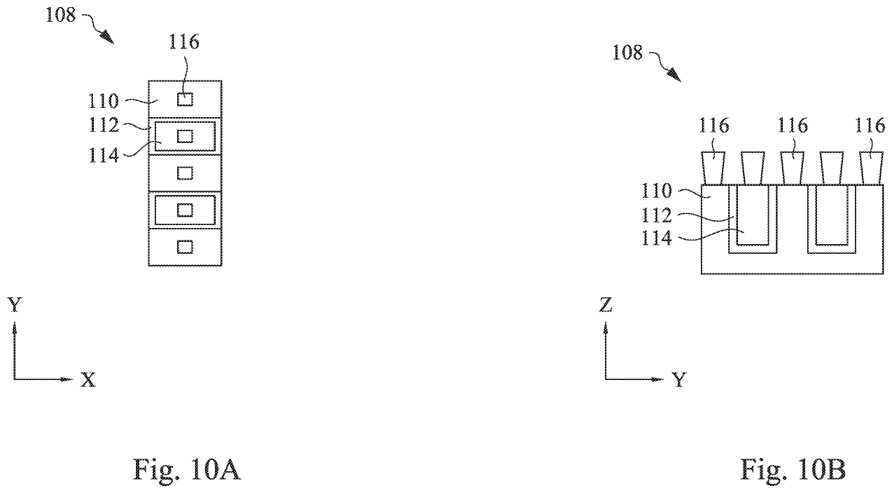

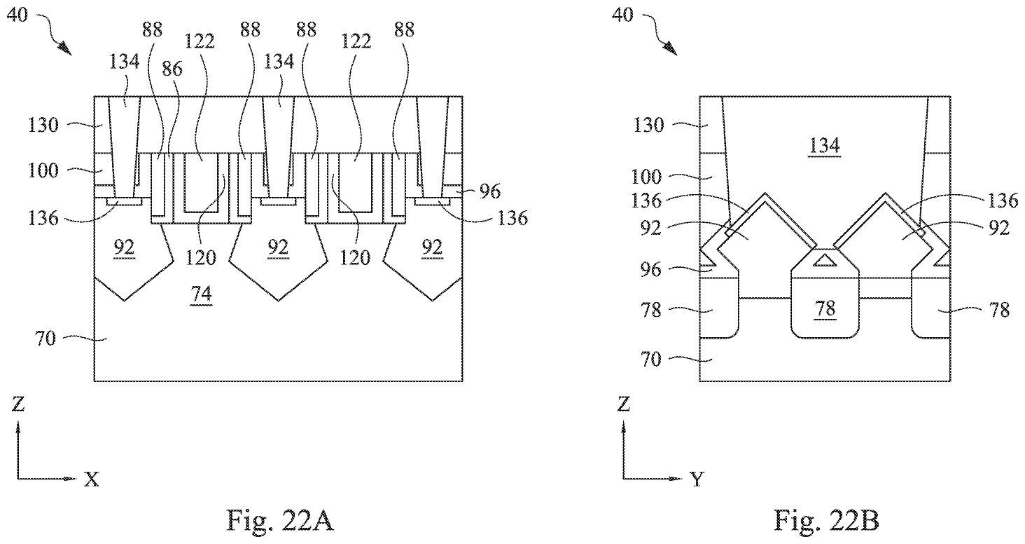

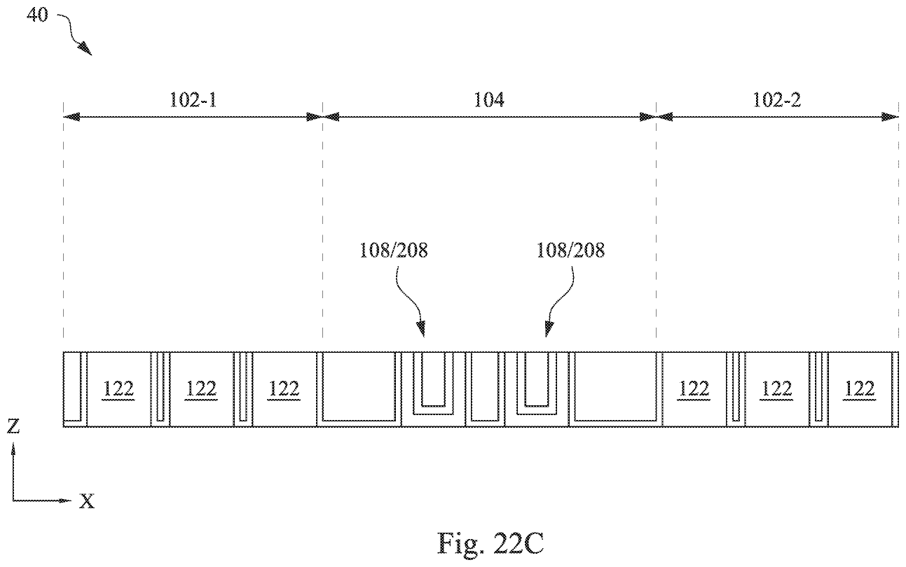

FIGS. 10A-B are various views of the MIM structure 108 of FIG. 9, in accordance with some embodiments. FIG. 10A is a top view of the MIM structure 108, and FIG. 10B is a cross-sectional side view of the MIM structure 108. In some embodiments, the first conductive layer 110 is not a conformal layer. For example, the first conductive layer 110 may be formed in the opening 106 (FIG. 8) to fill the opening 106 by any suitable process, such as PVD, ECP, or CVD. Then one or more openings are formed in the first conductive layer 110, and the dielectric layer 112 and the second conductive layer 114 are formed in the openings in the first conductive layer 110, as shown in FIGS. 10A and 10B. In some embodiments, the openings in the first conductive layer 110 extend through the first conductive layer 110 and separate the first conductive layer 110 into multiple discrete portions. In some embodiments, the dielectric layer 112 is in contact with the portions of the fins 74 or the dielectric layer 80. Next, a CMP process may be performed to remove the portions of the first conductive layer 110, the dielectric layer 112, and the second conductive layer 114 formed on the mask layer located in the IP blocks 102-1, 102-2. The mask layer located in the IP blocks 102-1, 102-2 may be also removed by the CMP process, and the resulting structure is shown in FIG. 10B. Conductive contacts 116 are then formed on the first and second conductive layers 110, 114, as shown in FIGS. 10A and 10B. The conductive contact 116 includes an electrically conductive material, such as a metal. In some embodiments, the conductive contact 116 includes tungsten, copper, aluminum, gold, silver, alloys thereof, the like, or a combination thereof. The conductive contacts 116 may be formed in a second ILD 130 (FIG. 22A), and the conductive contacts 116 may be formed at the same time as the conductive contacts for the gate electrode 122 (FIG. 22A).

In some embodiments, as shown in FIG. 10A, the length of the MIM structure 108 in the X direction is substantially small, such as less than about 90 nm, and the first conductive layer 110 and the second conductive layer 114 each has discrete portions. For example, the discrete portions of the first conductive layer 110 are aligned along the Y direction and are separated by the discrete portions of the second conductive layer 114. Each discrete portion of the second conductive layer 114 is surrounded by the dielectric layer 112, as shown in FIG. 10A. In some embodiments, the length of the MIM structure 108 is determined by the length of the gate electrode layer (or metal gate). The gate electrode layer may have a length greater than about 90 nm, and the first conductive layer 110 may be a continuous layer that surround multiple discrete portions of the second conductive layer 114.

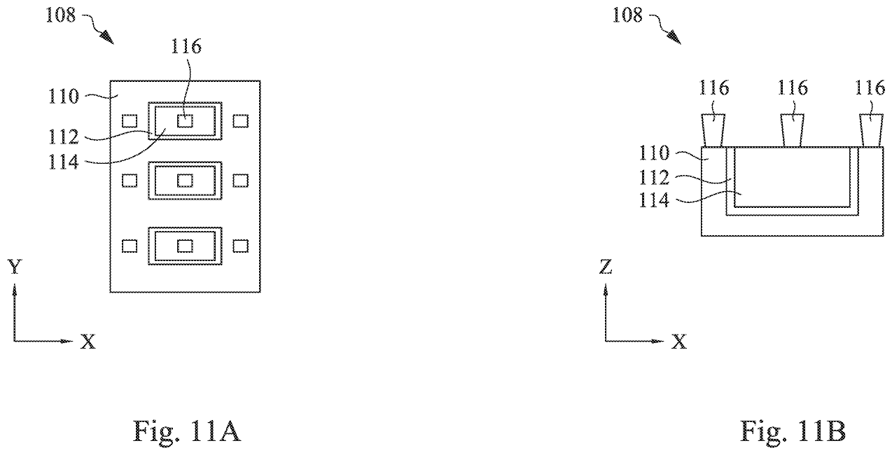

FIGS. 11A-B are various views of the MIM structure 108 of FIG. 9, in accordance with alternative embodiments. FIG. 11A is a top view of the MIM structure 108, and FIG. 11B is a cross-sectional side view of the MIM structure 108. As shown in FIG. 11A, the length of the MIM structure 108 is substantially greater than the length of the MIM structure 108 shown in FIG. 10A. In some embodiments, the length of the MIM structure 108 shown in FIG. 11A is greater than about 90 nm. With the greater length along the X direction, the openings formed in the first conductive layer 110 may not separate the first conductive layer 110 into discrete portions. In some embodiments, the first conductive layer 110 is a continuous layer having one or more openings filled with the dielectric layer 112 and discrete portions of the second conductive layer 114, as shown in FIG. 11A. Furthermore, in some embodiments, the openings in the first conductive layer 110 do not extend through the first conductive layer 110, and the dielectric layer 112 is formed on the first conductive layer 110, as shown in FIG. 11B. In some embodiments, the openings in the first conductive layer 110 extend through the first conductive layer, and the dielectric layer 112 is formed on the portions of the fins 74 or the dielectric layer 80. The first conductive layer 110, the dielectric layer 112, the second conductive layer 114, and the conductive contacts 116 may be formed by the same processes as the MIM structure 108 in FIGS. 10A and 10B. In some embodiments, as shown in FIG. 11B, the top surface of the first conductive layer 110 and the top surface of the second conductive layer 114 are substantially co-planar.

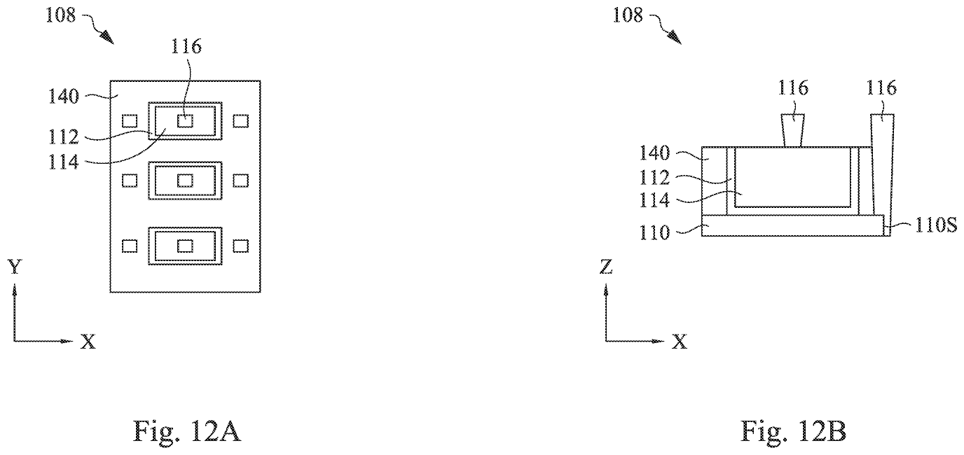

As shown in FIG. 11B, the conductive contacts 116 formed on the first conductive layer 110 are not in contact with the second conductive layer 114. Thus, the process window for forming the conductive contacts 116 on the first conductive layer 110 is substantially small. For example, the patterning process to form openings in the second ILD 130 (FIG. 22A) for the conductive contacts 116 to be formed on the first conductive layer 110 cannot expose the second conductive layer 114. In some embodiments, in order to enlarge the process window for forming the conductive contacts 116 on the first conductive layer 110, the MIM structure 108 is modified as shown in FIGS. 12A-B.

FIGS. 12A-B are various views of the MIM structure 108 of FIG. 9, in accordance with alternative embodiments. FIG. 12A is a top view of the MIM structure 108, and FIG. 12B is a cross-sectional side view of the MIM structure 108. As shown in FIG. 12B, the first conductive layer 110 is recessed from the level of the top surface of the second conductive layer 114, and a dielectric material 140 is formed on the first conductive layer 110 adjacent the second conductive layer 114. Thus, as shown in FIGS. 12A and 12B, the vertical sides of the second conductive layer 114 are surrounded by the dielectric material 140, and the bottom of the second conductive layer 114 is disposed over the first conductive layer 110 with the dielectric layer 112 disposed therebetween. In some embodiments, the dielectric material 140 may include a dielectric material having etch selectivity different from the material of the first ILD 100 (FIG. 6A). In some embodiments, the dielectric material is formed on the first ILD 100, and the dielectric material 140 may include the same material as the first ILD 100.

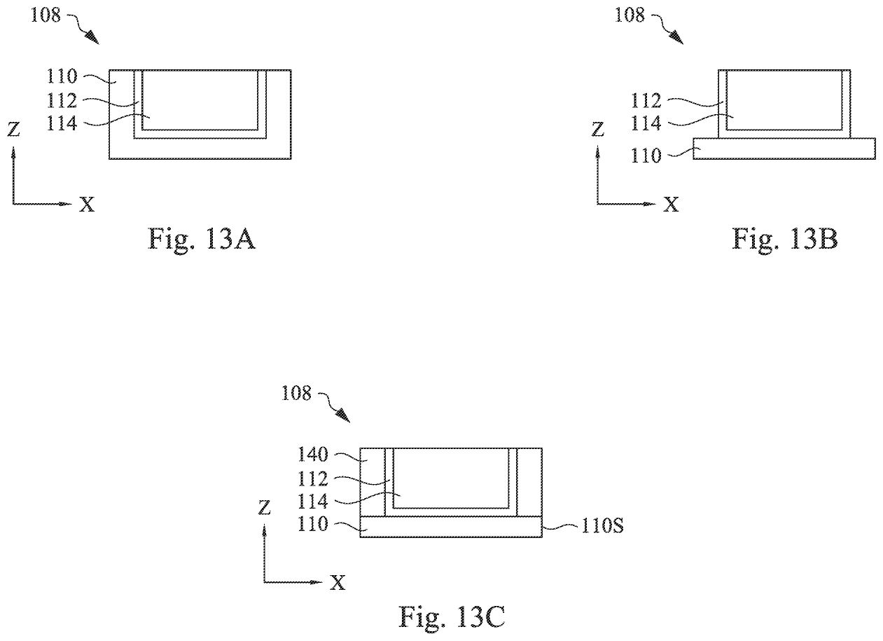

FIGS. 13A-C are cross-sectional side views of intermediate structures of the MIM structure 108 of FIGS. 12A-B, in accordance with some embodiments. To form the MIM structure 108 of FIGS. 12A-B, the MIM structure 108 shown in FIGS. 11A-B may be the starting point, as shown in FIG. 13A. Next, as shown in FIG. 13B, portions of the first conductive layer 110 disposed adjacent the vertical sides of the second conductive layer 114 are recessed. In some embodiments, the portions are completely removed, leaving the first conductive layer 110 having substantially constant thickness in the Z direction, as shown in FIG. 13B. In some embodiments, the portions are recessed, and the thickness of edge portions (portions without the second conductive layer 114 disposed thereon) of the first conductive layer 110 is substantially greater than the thickness of a center portion (portion with the second conductive layer 114 disposed thereon) of the first conductive layer 110. In some embodiments, the portions are completely removed with over etching. As a result, the thickness of the edge portions of the first conductive layer 110 is substantially less than the thickness of the center portion of the first conductive layer 110. The process to remove/recess the portions of the first conductive layer 110 disposed adjacent the vertical sides of the second conductive layer 114 may be a selective etch process that does not substantially affect the sacrificial gate layers 82, the gate spacer layers 86, 88, the first ILD 100 (or the dielectric material that is formed on the first ILD 100), the CESL 96, the dielectric layer 112, and the second conductive layer 114. In some embodiments, a portion of the second conductive layer 114 may be also removed by the selective etch process, and the resulting top surface of the second conductive layer 114 may have a concave profile.

Next, as shown in FIG. 13C, the dielectric material 140 is formed in the opening created by the removal/recessing of the portions of the first conductive layer 110. The dielectric material 140 may be formed by any suitable process. In some embodiments, the dielectric material 140 is formed by the same process as the first ILD 100. A planarization process, such as a CMP process, may be performed to remove portions of the dielectric material 140 formed in the IP blocks 102-1, 102-2 and on the second conductive layer 114, as shown in FIG. 13C. The dielectric material 140 may have a top surface that is substantially co-planar with the top surface of the second conductive layer 114. After the formation of the second ILD 130 (FIG. 22A), an opening is formed in the second ILD 130 and the dielectric material 140. In some embodiments, the opening is also formed in the CESL 96 and the first ILD 100, which are located adjacent the dielectric material 140, and a side surface 110S of the first conductive layer 110 may be exposed in the opening. The opening may be further away from the second conductive layer 114 compared to the opening for forming the conductive contact 116 shown in FIG. 11B. Next, the conductive contact 116 is formed in the opening, as shown in FIG. 12B. The conductive contact 116 may be in contact with a portion of a top surface of the first conductive layer 110 and the side surface 110S of the first conductive layer 110. Because of having the dielectric material 140, the process window for forming the conductive contact 116 is enlarged.

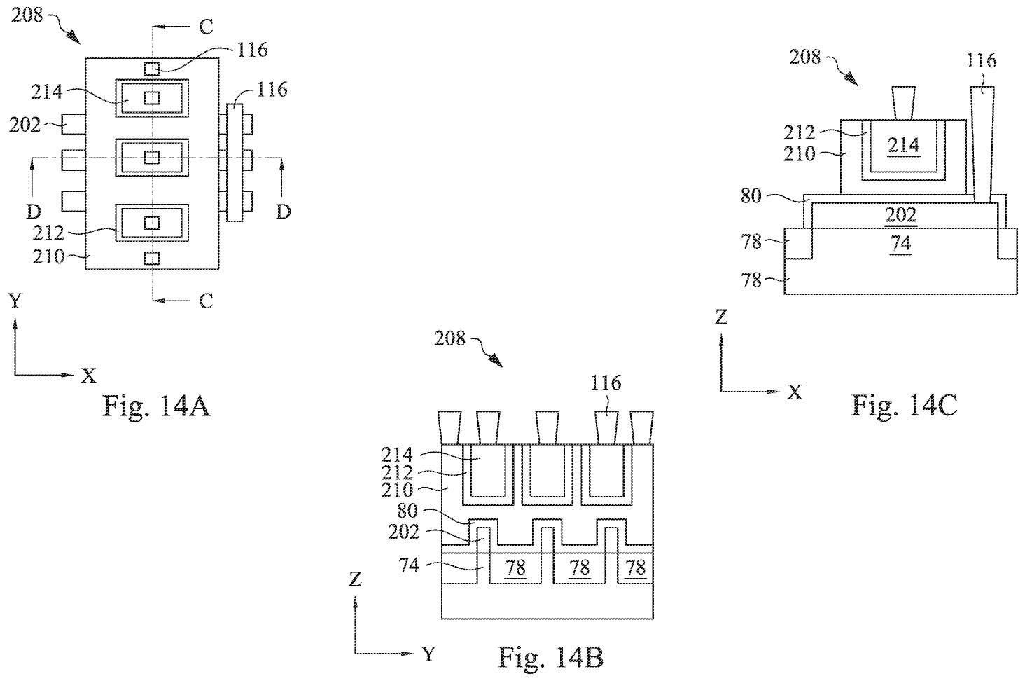

FIGS. 14A-C are various views of a MIM structure 208, in accordance with some embodiments. FIG. 14A is a top view of the MIM structure 208, FIG. 14B is a cross-sectional side view of the MIM structure 208 of FIG. 14A taken along line C-C, and FIG. 14C is a cross-sectional side view of the MIM structure 208 of FIG. 14A taken along line D-D. As shown in FIGS. 14A-C, the MIM structure 208 includes more than one MIM capacitor. In some embodiments, a first MIM capacitor includes a first conductive layer 202 and a second conductive layer 210 separated by a dielectric layer 80, and a second MIM capacitor includes the second conductive layer 210 and a third conductive layer 214 separated by a dielectric layer 212.

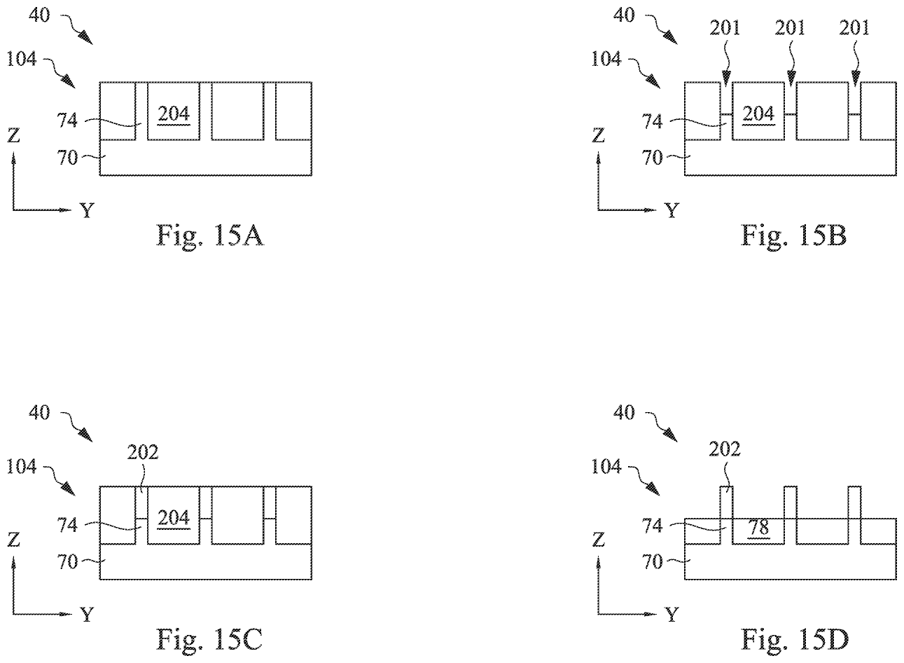

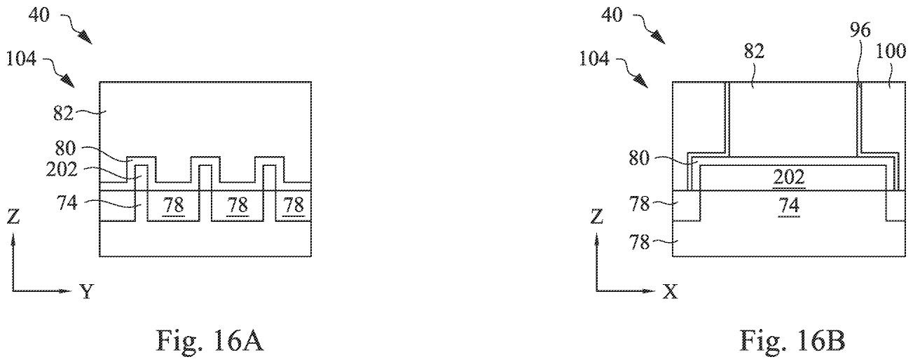

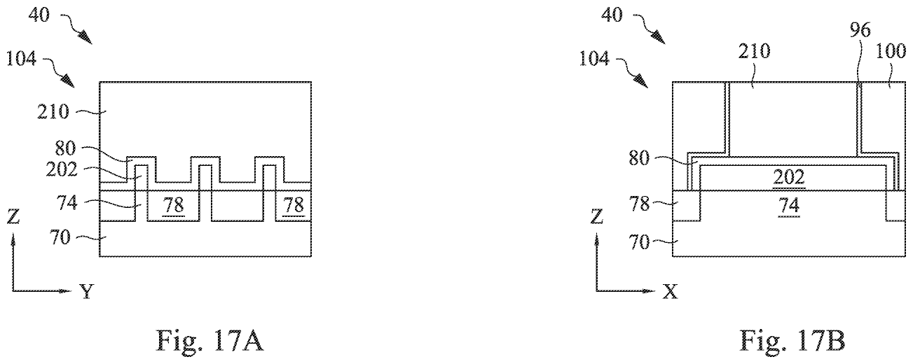

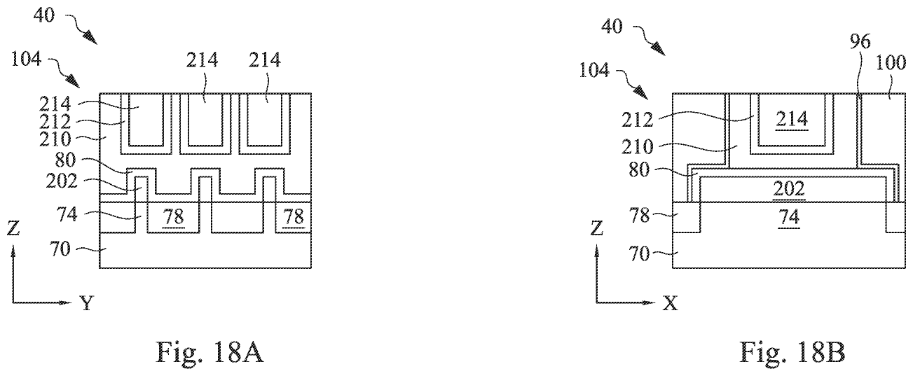

FIGS. 15A-D, 16A-B, 17A-B, 18A-B, and 19A-B are various views of respective intermediate structures at intermediate stages in an example process of forming the semiconductor device structure 40 including the MIM structure 208 of FIGS. 14A-C, in accordance with some embodiments. FIGS. 15A-D are cross-sectional side views of the border region 104 of the semiconductor device structure 40 of FIG. 1C taken along line B-B. As shown in FIG. 15A, the semiconductor device structure 40 is at a stage prior to the formation of the isolation regions 78. The fins 74 are formed from the semiconductor substrate 70, and a dielectric material 204 is formed between adjacent fins 74. The dielectric material 204 may be also formed on the top surfaces of the fins 74, and a planarization process, such as a CMP process, may be performed to remove portions of the dielectric material 204 and to expose the top surfaces of the fins 74. The dielectric material 204 may include the same material as the isolation region 78. Next, a mask layer (not shown) is formed in the IP blocks 102-1, 102-2 (FIG. 8) to protect the fins 74 and the dielectric material 204 formed in the first and second IP blocks 102-1, 102-2, and a portion of each fin 74 in the border region 104 are removed, as shown in FIG. 15B. The portions of the fins 74 may be removed by any suitable process, such as a dry etch, wet etch, or a combination thereof. The etch process may be a selective etch process that does not substantially affect the dielectric material 204. Openings 201 are formed over the remaining fins 74 in the border region 104.

Next, as shown in FIG. 15C, the first conductive layer 202 is formed in the openings 201. The first conductive layer 202 may include the same material as the first conductive layer 110 and may be formed by the same process as the first conductive layer 110. The first conductive layer 202 may be also formed on the dielectric material 204 in the border region 104 and on the mask layer in the first and second IP blocks 102-1, 102-2. A planarization process, such as a CMP process, may be performed to remove the portions of the first conductive layer 202 formed on the dielectric material 204 in the border region 104 and on the mask layer in the first and second IP blocks 102-1, 102-2. The CMP process may also remove the mask layer in the first and second IP blocks 102-1, 102-2. As shown in FIG. 15D, the dielectric material 204 is recessed to form the isolation regions 78. In some embodiments, the semiconductor device structure 40 includes fins 74 extending over the isolation regions 78 in the first and second IP blocks 102-1, 102-2 and first conductive layer 202 extending over the isolation regions 78 in the border region 104. In some embodiments, the isolation region 78 includes a top surface located at or below a level of a top surface of the remaining fin 74 in the border region 104, as shown in FIG. 15D.

Next, processes, such as the processes described in FIGS. 2A to 6B, are performed on the semiconductor device structure 40. The resulting semiconductor device structure 40 in the first and second IP blocks 102-1, 102-2 is shown in FIGS. 6A and 6B, and the resulting semiconductor device structure 40 in the border region 104 is shown in FIGS. 16A and 16B. As shown in FIGS. 16A and 16B, the dielectric layer 80 is formed on the first conductive layer 202, and the sacrificial gate layer 82 is formed on the dielectric layer 80. The gate spacer layers 86, 88 are omitted in FIG. 16B for clarity. The CESL 96 and the first ILD 100 are formed over portions of the first conductive layer 202, as shown in FIG. 16B, and the planarization process is performed to expose the sacrificial gate layer 82.

As shown in FIGS. 17A and 17B, a mask layer (not shown) is formed in the first and second IP blocks 102-1, 102-2 to protect the materials in the first and second IP blocks 102-1, 102-2, and the exposed sacrificial gate layers 82 in the border region 104 are removed and replaced with the second conductive layer 210. In some embodiments, the gate spacer layers 86, 88 in the border region 104 are also removed. In the embodiment shown in FIGS. 17A and 17B, the dielectric layer 80 is not removed and remains on the first conductive layer 202. The dielectric layer 80 functions as an insulator in a MIM capacitor of the MIM structure 208 (FIGS. 14A-C). The second conductive layer 210 may include the same material as the first conductive layer 110 and may be formed by the same process as the first conductive layer 110. The second conductive layer 210 may be formed in the openings 106 (FIG. 8).

As shown in FIGS. 18A and 18B, openings are formed in the second conductive layer 210, and the dielectric layer 212 and the third conductive layer 214 are formed in the openings. The dielectric layer 212 may include the same material as the dielectric layer 112 and may be formed by the same process as the dielectric layer 112. The third conductive layer 214 may include the same material as the second conductive layer 114 and may be formed by the same process as the second conductive layer 114. Portions of the second conductive layer 210, the dielectric layer 212, and the third conductive layer 214 may be formed on the mask layer (not shown) formed in the IP blocks 102-1, 102-2, and a CMP process may be performed to remove the portions of the second conductive layer 210, the dielectric layer 212, and the third conductive layer 214 formed on the mask layer located in the IP blocks 102-1, 102-2. The mask layer located in the IP blocks 102-1, 102-2 may be also removed by the CMP process. The resulting semiconductor device structure 40 may include sacrificial gate layers 82 located in the first and second IP blocks 102-1, 102-2 having top surfaces substantially co- planar with top surfaces of the second and third conductive layers 210, 214 located in the border region 104.

After replacing the sacrificial gate layers 82 in the first and second IP blocks 102-1, 102-2 with the gate electrodes 122 (FIG. 22A) and forming the second ILD 130 (FIG. 22A), conductive contacts 116 are formed on the second and third conductive layers 210, 214, as shown in FIGS. 19A and 19B. The conductive contact 216 in contact with the first conductive layer 202 may extend through the first ILD 100 and the CESL 96, as shown in FIG. 19B. Furthermore, the length of the first conductive layer 202 in the X direction is substantially greater than the length of the second conductive layer 214 in order to receive the conductive contact 116.

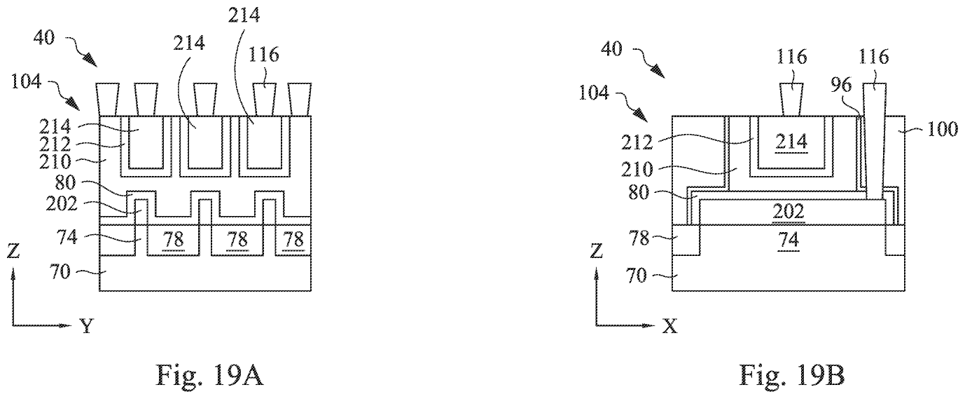

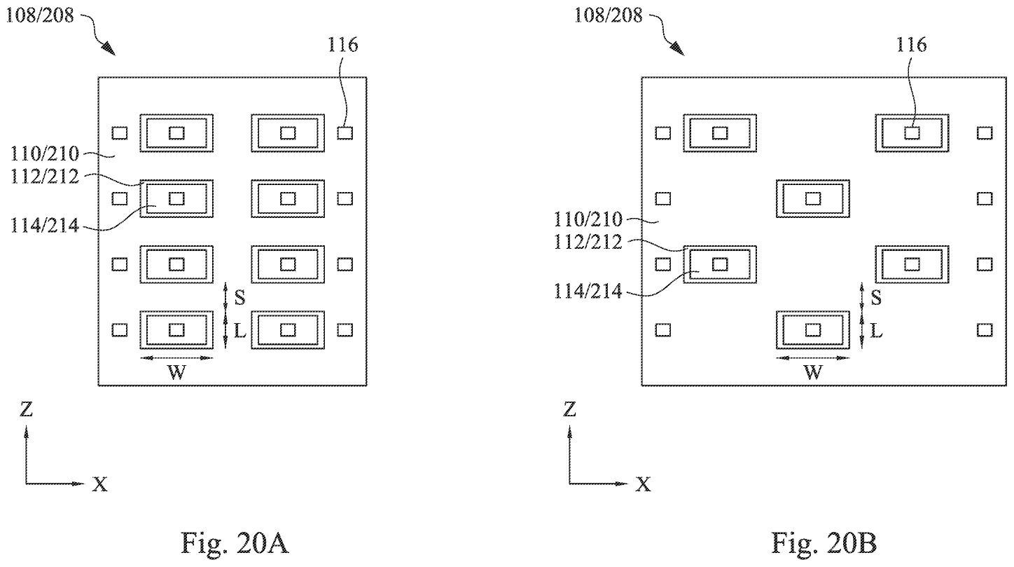

FIGS. 20A-B are top views of the MIM structure 108 of FIGS. 11A-B or the MIM structure 208 of FIGS. 19A-B, in accordance with alternative embodiments. As shown in FIGS. 20A-B, the conductive layer 114/214 may be arranged in any suitable pattern. In some embodiments, the conductive layer 114/214 and the dielectric layer 112/212 together have a width W and a length L, and the adjacent conductive layers 114/214 and the dielectric layers 112/212 are separated by a distance S in the Y direction. In some embodiments, the width W, length L, and the distance S may be greater than about 0.144 μm. As a result, CMP dishing effect may be reduced.

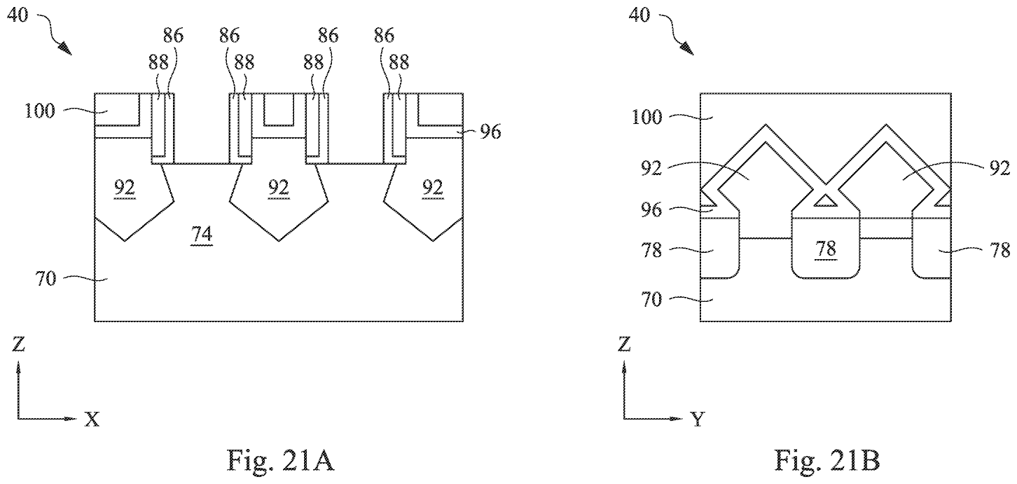

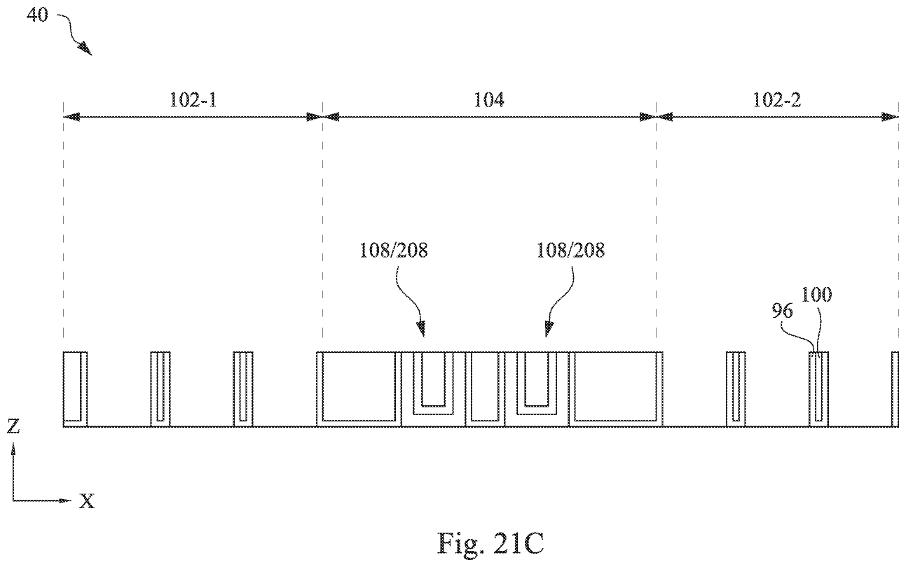

FIGS. 21A-C are cross-sectional views of intermediate structures at intermediate stages in the example process of forming the semiconductor device structure 40, in accordance with some embodiments. FIGS. 21A-B illustrates the semiconductor device structure 40 in the first and second IP blocks 102-1, 102-2. The gate spacer layers 86, 88 are omitted in FIG. 21C for clarity. As shown in FIGS. 21A-C, a mask layer (not shown) is formed on the MIM structure 108/208 in the border region 104, and the sacrificial gate layers 82 in the first and second IP blocks 102-1, 102-2 are removed. The sacrificial gate layers 82 may be removed by any suitable process. In some embodiments, the dielectric layer 80 disposed under the sacrificial gate layers 82 are also removed. After the sacrificial gate layers 82 and the dielectric layers 80 are removed, the replacement gate structures are formed in the recesses where the gate stacks were removed.

FIGS. 22A-C are cross-sectional views of intermediate structures at intermediate stages in the example process of forming the semiconductor device structure 40, in accordance with some embodiments. FIGS. 22A-B illustrates the semiconductor device structure 40 in the first and second IP blocks 102-1, 102-2. The gate spacer layers 86, 88 are omitted in FIG. 22C for clarity. As shown in FIGS. 22A-C, the replacement gate structures each include one or more conformal layers 120 and a gate electrode 122. The one or more conformal layers 120 include a gate dielectric layer and may include one or more work-function tuning layers. The gate dielectric layer can be conformally deposited in the recesses where gate stacks were removed. The gate dielectric layer can be or include silicon oxide, silicon nitride, a high-k dielectric material, multilayers thereof, or other dielectric material. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, other suitable high-k dielectric materials, and/or combinations thereof. Then, the gate electrodes 122 are formed over the one or more conformal layers 120. The layer for the gate electrodes 122 can fill remaining recesses where the gate stacks were removed. The gate electrodes 122 may include one or more layers of electrically conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof.

In some embodiments, the gate electrodes 122 includes p-type gate electrodes and n-type gate electrodes. For example, the gate electrodes 122 formed in the first IP block 102-1 are n-type gate electrodes, and the gate electrodes 122 formed in the second IP block 102-2 are p-type gate electrodes. The n-type and p-type gate electrodes 122 may be formed by first depositing a first type, such as n-type or the p-type, gate electrodes 122 in both the first and second IP blocks 102-1, 102-2. Then, a planarization process, such as a CMP process, is performed to remove the portions of the first type gate electrodes 122 formed on the first ILD 100 and in the border region 104. The mask layer formed in the border region 104 to protect the MIM structures 108/208 may be also removed by the CMP process. As described above, because the MIM structures 108/208 include multiple materials, the CMP dishing effect is reduced. Next, another mask layer is formed in the first IP block 102-1 and the border region 104 to protect the first type gate electrodes and the MIM structures 108/208. The first type gate electrodes 122 formed in the second IP block 102-2 are removed, and a second type opposite the first type gate electrode is formed in the second IP block 102-2. Another CMP process is then performed to remove portions of the second type gate electrode formed in the first IP block 102-1 and the border region 104, and the mask layer formed in the first IP block 102-1 and the border region 104 is also removed by the CMP process. The resulting semiconductor device structure 40 is shown in FIG. 22C. In some embodiments, a top surface of the gate electrode 122 and a top surface of the MIM structure 108/208/308 may be substantially co-planar, as shown in FIG. 22C. The top surface of the MIM structure 108/208/308 may include a top surface of the conductive layer 110 (FIGS. 10B, 11B), a top surface of the conductive layer 114 (FIGS. 10B, 11B, 12B), a top surface of the dielectric material 140 (FIG. 12B), a top surface of the conductive layer 210 (FIG. 14B), and/or a top surface of the conductive layer 214 (FIG. 14B).

Next, as shown in FIGS. 22A and 22B, the second ILD 130 is formed over the replacement gate structures, the first ILD 100, and the MIM structures 108/208, and conductive features 134 are formed through the second ILD 130, the first ILD 100, and the CESL 96 to the epitaxy source/drain regions 92. Although not illustrated, in some examples, an etch stop layer (ESL) may be deposited over the first ILD 100, etc., and the second ILD 130 may be deposited over the ESL. If implemented, the ESL may include or be silicon nitride, silicon carbon nitride, silicon carbon oxide, carbon nitride, the like, or a combination thereof. The second ILD 130 may include or be silicon dioxide, a low-k dielectric material, such as silicon oxynitride, PSG, BSG, BPSG, USG, FSG, OSG, SiOₓC_{y}, spin-on-glass, spin-on-polymers, silicon carbon material, a compound thereof, a composite thereof, the like, or a combination thereof. The conductive features 134 may be formed through the second ILD 130, first ILD 100, and CESL 96 to the epitaxy source/drain regions 92. Silicide regions 136 may be formed on upper portions of the epitaxy source/drain regions 92 by reacting upper portions of the epitaxy source/drain regions 92 with the conductive features 134. The conductive contacts 116 for the MIM structures 108/208 may be formed before, after, or simultaneously with the conductive features 134. In some embodiments, the conductive contacts 116 are formed after the formation of the conductive features 134 and are formed simultaneously with conductive features (not shown) for the gate electrodes 122. The second ILD 130, the conductive features 134, and the conductive contacts 116 are omitted in FIG. 22C for clarity.

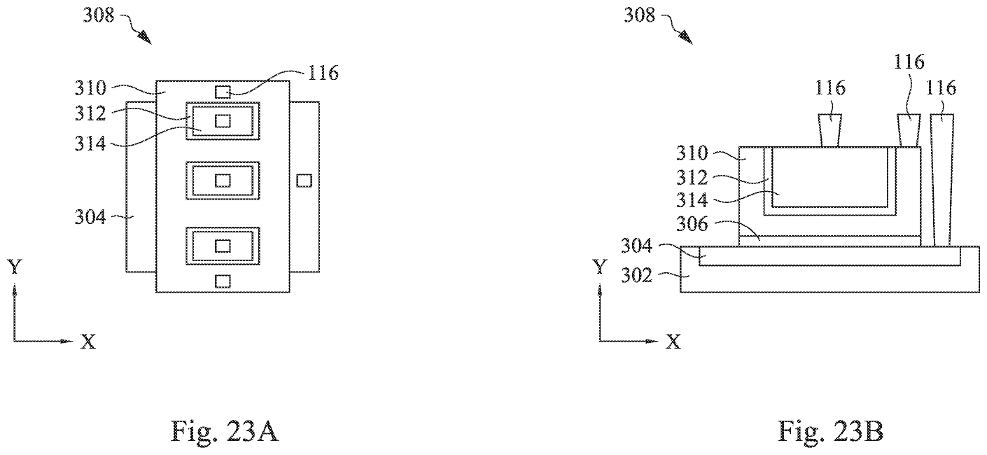

FIGS. 23A-B are various views of a MIM structure 308, in accordance with alternative embodiments. The semiconductor device structure 40 including the MIM structures 108/208 shown in the previous figures is based on FinFETs. The MIM structures in the border region 104 to reduce CMP dishing effect may be applied to other types of devices, such as planar FETs, nanostructure FETs, Horizontal Gate All Around (HGAA) FETs, Vertical Gate All Around (VGAA) FETs, and other suitable devices. In some embodiments, planar FETs are formed in the first and second IP blocks 102-1, 102-2, and MIM structures 308 are formed in the border region 104. As shown in FIGS. 23A-B, the MIM structure 308 is formed over a semiconductor substrate 302, which may include the same material as the semiconductor substrate 70. A first conductive layer 304 is formed in the semiconductor substrate 302. The first conductive layer 304 may include the same material as the first conductive layer 202 and may be formed by the same process as the first conductive layer 202. A mask layer may be formed in the first and second IP blocks 102-1, 102-2 and expose a portion of the semiconductor substrate 302 located in the border region 104. An opening is formed in the exposed portion of the semiconductor substrate 302, and the first conductive layer 304 is formed in the opening.

Next, a dielectric layer 306 is formed on the first conductive layer 304. The dielectric layer 306 may include the same material as the dielectric layer 80 and may be formed by the same process as the dielectric layer 80. The dielectric layer 306 may be also formed in the first and second IP blocks 102-1, 102-2. The dielectric layer 306 may be formed by first forming a continuous layer in the first and second IP blocks 102-1, 102-2 and the border region 104. Then, a patterning process is performed on the continuous layer to form the dielectric layer 306. A sacrificial gate layer (not shown) is formed on the dielectric layer 306 in the first and second IP blocks 102-1, 102-2 and the border region 104. Gate spacer layers (not shown) may be formed on opposite sides of the sacrificial gate layer in the first and second IP blocks 102-1, 102-2. The gate spacer layers may include the same material as the gate spacer layers 86, 88 and may be formed by the same process as the gate spacer layers 86, 88. In some embodiments, the gate spacer layers are not formed in the border region 104, which may be achieved by forming a mask layer in the border region 104 prior to the formation of the gate spacer layers. Still with the mask layer formed in the border region 104, source/drain regions (not shown) may be formed on opposite sides of the sacrificial gate layer in the first and second IP blocks 102-1, 102-2. After the formation of the source/drain regions, the mask layer in the border region 104 is removed, and a CESL and a first ILD is formed in the first and second IP blocks 102-1, 102-2 and the border region 104.

Next, a mask layer is formed in the first and second IP blocks 102-1, 102-2 to protect the sacrificial gate layers located therein, and the exposed sacrificial gate layers in the border region 104 are removed. A second conductive layer 310 is formed in the openings created by the removal of the sacrificial gate layers. The second conductive layer 310 may include the same material as the second conductive layer 210 and may be formed by the same process as the second conductive layer 310. Openings are formed in the second conductive layer 310. A dielectric layer 312 and a third conductive layer 314 are formed in each opening in the second conductive layer 310. The dielectric layer 312 may include the same material as the dielectric layer 212 and may be formed by the same process as the dielectric layer 212. The third conductive layer 314 may include the same material as the third conductive layer 214 and may be formed by the same process as the third conductive layer 214. In some embodiments, the MIM structure 308 include a first MIM capacitor having the first conductive layer 304, the dielectric layer 306, and the second conductive layer 310 and a second MIM capacitor having the second conductive layer 310, the dielectric layer 312, and the third conductive layer 314. After forming the MIM structure 308 in the border region 104, a mask layer is formed in the border region 104, and processes, such as the processes described in FIGS. 21A-C and 22A-C are performed in the first and second IP blocks 102-1, 102-2 to complete the planar FETs. The conductive contacts 116 are then formed in a second ILD (not shown), such as the second ILD 130 (FIG. 22A).

The present disclosure in various embodiments provides a semiconductor device structure and methods for forming the same. In some embodiments, the semiconductor device structure 40 includes a MIM structure 108/208/308 located in a border region 104. The MIM structure 108/208/308 may include one or more MIM capacitors. Some embodiments may achieve advantages. For example, with the MIM structure 108/208/308 formed in the border region 104, CMP dishing effect is reduced when forming the gate electrodes 122. Furthermore, MIM structure 108/208/308 located in FEOL may conserve metal routing to reduce IR drop compared to MIM structure in BEOL.

An embodiment is a semiconductor device structure. The structure includes a first region including a gate electrode disposed over a semiconductor fin, a second region, and a border region disposed between the first and second regions. The border region includes a metal-insulator-metal (MIM) structure, and the MIM structure includes a first conductive layer disposed over the semiconductor fin, a first dielectric layer in contact with the first conductive layer, and a second conductive layer in contact with the first dielectric layer. A top surface of the second conductive layer and a top surface of the gate electrode may be substantially co-planar.

Another embodiment is a semiconductor device structure. The structure includes a first region including a gate electrode, a second region, and a border region disposed between the first and second regions. The border region comprises a metal-insulator-metal (MIM) structure, and the MIM structure includes a first conductive layer, a first dielectric layer in contact with the first conductive layer, and a second conductive layer in contact with the first dielectric layer. A top surface of the second conductive layer and a top surface of the first conductive layer may be substantially co-planar.

A further embodiment is a method. The method includes forming a fin over a substrate, and the fin is disposed in a first region, a second region, and a border region disposed between the first and second regions. The method further includes forming a first sacrificial gate layer over a first portion of the fin located in the first region, a second sacrificial gate layer over a second portion of the fin located in the second region, and a third sacrificial gate layer over a third portion of the fin located in the border region. The method further includes removing the third sacrificial gate layer to create an opening, forming a metal-insulator-metal (MIM) structure in the opening, removing the first and second sacrificial gate layers to form openings in the first and second regions, and depositing gate electrodes in the openings in the first and second regions. Top surfaces of the gate electrodes and a top surface of the MIM structure are substantially co-planar.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first region comprising a gate electrode disposed over a semiconductor fin;
a second region; and
a border region disposed between the first and second regions, wherein the border region comprises a metal-insulator-metal (MIM) structure, and the MIM structure comprises:
a first conductive layer disposed over the semiconductor fin;
a first dielectric layer in contact with the first conductive layer; and
a second conductive layer in contact with the first dielectric layer, wherein a top surface of the second conductive layer and a top surface of the gate electrode may be substantially co-planar.

2. The semiconductor device structure of claim 1, wherein the first conductive layer is disposed adjacent vertical sides of the second conductive layer, and the first dielectric layer is disposed between the first conductive layer and the vertical sides of the second conductive layer.

3. The semiconductor device structure of claim 1, wherein the first dielectric layer is in contact with the semiconductor fin.

4. The semiconductor device structure 1, further comprising a dielectric material surrounding vertical sides of the second conductive layer, wherein the dielectric material is disposed on the first conductive layer.

5. The semiconductor device structure of claim 4, wherein the first dielectric layer is in contact with the dielectric material.

6. The semiconductor device structure of claim 5, wherein a top surface of the dielectric material and the top surface of the second conductive layer are substantially co-planar.

7. The semiconductor device structure of claim 1, wherein a width of the border region is between 0.1 μm and 3.0 μm.

8. The semiconductor device structure of claim 1, wherein the second conductive layer and the first dielectric layer has a combined length and a combined width, and the combined length and the combined width are greater than 0.144 μm.

9. The semiconductor device structure of claim 1, further comprising a third conductive layer disposed on the semiconductor fin and a second dielectric layer disposed on the third conductive layer, wherein the first conductive layer is in contact with the second dielectric layer.

10. A semiconductor device structure, comprising:
a first region comprising a gate electrode;
a second region; and
a border region disposed between the first and second regions, wherein the border region comprises a metal-insulator-metal (MIM) structure, and the MIM structure comprises:
a first conductive layer;
a first dielectric layer in contact with the first conductive layer; and
a second conductive layer in contact with the first dielectric layer, wherein a top surface of the second conductive layer and a top surface of the first conductive layer may be substantially co-planar.

11. The semiconductor device structure of claim 10, further comprising a third conductive layer disposed below the first conductive layer and a second dielectric layer disposed between the first conductive layer and the third conductive layer.

12. The semiconductor device structure of claim 11, wherein a width of the third conductive layer is substantially greater than a width of the first conductive layer.

13. The semiconductor device structure of claim 11, further comprising a contact etch stop layer in contact with the first conductive layer and the second dielectric layer and an interlayer dielectric disposed on the contact etch stop layer.

14. The semiconductor device structure of claim 13, further comprising a conductive contact disposed through the interlayer dielectric, the contact etch stop layer, and the second dielectric layer, wherein the conductive contact is in contact with the third conductive layer.

15. The semiconductor device structure of claim 13, wherein a top surface of the interlayer dielectric and the top surface of the second conductive layer are substantially co-planar.

16. The semiconductor device structure of claim 13, wherein the contact etch stop layer and the interlayer dielectric are disposed adjacent the gate electrode.

17. A method, comprising:
forming a fin over a substrate, wherein the fin is disposed in a first region, a second region, and a border region disposed between the first and second regions;
forming a first sacrificial gate layer over a first portion of the fin located in the first region, a second sacrificial gate layer over a second portion of the fin located in the second region, and a third sacrificial gate layer over a third portion of the fin located in the border region;
removing the third sacrificial gate layer to create an opening;
forming a metal-insulator-metal (MIM) structure in the opening;
removing the first and second sacrificial gate layers to form openings in the first and second regions; and
depositing gate electrodes in the openings in the first and second regions, wherein top surfaces of the gate electrodes and a top surface of the MIM structure are substantially co-planar.

18. The method of claim 17, wherein forming the MIM structure comprises depositing a first conductive layer in the opening, depositing a dielectric layer on the first conductive layer, and depositing a second conductive layer on the dielectric layer.

19. The method of claim 18, wherein forming the MIM structure further comprises removing portions of the first conductive layer and depositing a dielectric material to surround vertical sides of the second conductive layer.

20. The method of claim 17, further comprising recessing the third portion of the fin and depositing a third conductive layer on the recessed third portion of the fin prior to forming the third sacrificial gate layer.
